(19) United States
(12) Patent Application Publication
(10) Pub. No.: US 2010/0193862 A1
(43) Pub. Date: Aug. 5, 2010

(54) SEMICONDUCTOR DEVICE AND METHOD OF MANUFACTURING THE SAME

(75) Inventor: Masaaki KANAZAWA, Kanagawa (JP)

Correspondence Address: YOUNG & THOMPSON, 209 Madison Street, Suite 500, Alexandria, VA, 22314, US

(73) Assignee: NEC ELECTRONICS CORPORATION, Kanagawa (JP)

(21) Appl. No.: 12/700,908

(22) Filed: Feb. 5, 2010

(30) Foreign Application Priority Data
Feb. 5, 2009 (JP) 2009-024694

(51) Int. Cl. H01L 29/78; H01L 21/336

(52) U.S. Cl. 257/330; 438/589; 438/270; 257/E21.41; 257/E29.262

(57) ABSTRACT

A method of manufacturing according to the present invention includes forming a trench to a semiconductor substrate, depositing an insulating film to the trench, etching the insulating film of a bottom part of the trench by plasma etching and thereby forming to an opening part of the trench, an inclined surface at an angle of inclination a to a principal surface of the semiconductor substrate, forming a gate insulating film from a top surface of the semiconductor substrate to the insulating film of the bottom part of the trench, and forming a gate electrode on the gate insulating film.

### INCORPORATION BY REFERENCE

This application is based upon and claims the benefit of priority from Japanese patent application No. 2009-024694, filed on Feb. 5, 2009, the disclosure of which is incorporated herein in its entirety by reference.

### BACKGROUND

1. Field of the Invention

The present invention relates to a semiconductor device having a trench gate structure and a method of manufacturing the same.

2. Description of Related Art

In an insulated gate semiconductor device having a trench gate structure, it is known that electric fields are concentrated in the gate insulating film of the part to cover corners of the trench bottom, and this causes to reduce the withstand pressure.

As illustrated in FIG. 5, Japanese Unexamined Patent Application Publication No. 2005-116822 discloses a semiconductor substrate 210 that is composed of an N⁺ drain region 211, an N⁻ drift region 212, a P⁻ body region 241, an N⁺ source region 231, and a P⁺ contact region 232. A trench 221 is formed in the semiconductor substrate 210. A P floating area 251 is formed in the lower part of the trench 221. Then, by the insulating film 223 provided to the bottom part of the trench 221, the bottom part of the trench 221 and the gate electrode 222 are separated. This reduces the concentration of the electric fields in the bottom part of the trench 221 and thereby preventing from reducing the withstand pressure.

### SUMMARY

However, a detailed analysis by the present inventor has found the following problem. In the abovementioned method, the insulating film 223 deposited over the semiconductor substrate 210 is etched, as illustrated in FIG. 6A. In this case, as illustrated in FIG. 6B, a sheer trench opening top edge 225 is formed in a trench opening part 221a. The trench opening top edge 225 is at an angle of inclination of 85 degrees<=β<=90 degrees to a semiconductor substrate principal surface 210a. Therefore, the thickness of the gate insulating film 224 that covers the trench opening top edge 225 is not uniform and is locally thin in the part of the trench opening top edge 225. Electric fields are concentrated in the part where the gate insulating film 224 is thin, thereby causing to reduce the withstand pressure.

As a countermeasure against the above problem, as illustrated in FIG. 6C, after the trench 221 is formed, it can be oxidized to be rounded off. This enables to form a round oxidized surface 225 to have a round surface to the trench opening part 221a.

Further, in Japanese Unexamined Patent Application Publication No. 2006-228901, as illustrated in FIGS. 1A to 2C according to Japanese Unexamined Patent Application Publication No. 2006-228901, a trench is formed by plasma etching. Then the trench opening top edge can be rounded by carrying out a further plasma etching with different conditions.

However, The present inventor has found a problem that even when using these methods, by carrying out a plasma etching to leave a thick insulating film only in the bottom part of the trench, the round surface of the trench opening part 221 a is removed. Therefore, the sheer trench opening top edge 225 is formed again and thus it is unable to prevent from reducing the withstand pressure.

An exemplary aspect of an embodiment of the present invention is a method of manufacturing a semiconductor device that includes forming a trench to a semiconductor substrate, depositing an insulating film to the trench, etching the insulating film of a bottom part of the trench by plasma etching and thereby forming to an opening part of the trench, an inclined surface at an angle of inclination a to a principal surface of the semiconductor substrate, forming a gate insulating film from a top surface of the semiconductor substrate to the insulating film of the bottom part of the trench, and forming a gate electrode on the gate insulating film.

This suppresses the gate insulating film that covers the trench opening part from being locally thin and thus prevents from reducing the withstand pressure.

Another exemplary aspect of an embodiment of the present invention is a semiconductor device that includes a semiconductor substrate having a trench formed thereto, an insulating film formed to a bottom part of the trench, a gate insulating film formed to an inner wall of the trench and is thinner than the insulating film, and a gate electrode surrounded by the gate insulating film. The trench has an inclined surface at an angle of inclination a to a principal surface of the semiconductor substrate formed to an opening part, and the angle of inclination a is 45 degrees<=a<=75 degrees.

This suppresses the gate insulating film that covers the trench opening part from being locally thin and thus prevents from reducing the withstand pressure.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1A is a cross-sectional diagram illustrating the configuration of a semiconductor device according to a first exemplary embodiment;

FIG. 1B is an enlarged cross-sectional diagram of a trench opening part illustrating the configuration of the semiconductor device according to the first exemplary embodiment;

FIG. 2A is a cross-sectional diagram illustrating the manufacturing process of the semiconductor device according to the first exemplary embodiment;

FIG. 2B is a cross-sectional diagram illustrating the manufacturing process of the semiconductor device according to the first exemplary embodiment;

FIG. 2C is a cross-sectional diagram illustrating the manufacturing process of the semiconductor device according to the first exemplary embodiment;

FIG. 2D is a cross-sectional diagram illustrating the manufacturing process of the semiconductor device according to the first exemplary embodiment;

FIG. 2E is a cross-sectional diagram illustrating the manufacturing process of the semiconductor device according to the first exemplary embodiment;

FIG. 2F is a cross-sectional diagram illustrating the manufacturing process of the semiconductor device according to the first exemplary embodiment;

FIG. 2G is a cross-sectional diagram illustrating the manufacturing process of the semiconductor device according to the first exemplary embodiment;

FIG. 3 is a graph indicating an experimental result on the relationship between an angle of inclination a and an electrostatic breakdown voltage according to a second exemplary embodiment;

FIG. 4 is a block diagram of a parallel plate plasma etching device according to the second exemplary embodiment;

FIG. 5 is a cross-sectional diagram illustrating the configuration of the semiconductor device disclosed in Japanese Unexamined Patent Application Publication No. 2005-116822;

FIG. 6A is a cross-sectional diagram of a plasma etching process of the semiconductor device disclosed in Japanese Unexamined Patent Application Publication No. 2005-116822;

FIG. 6B is an enlarged cross-sectional diagram of a trench opening part in the plasma etching process of the semiconductor device disclosed in Japanese Unexamined Patent Application Publication No. 2005-116822; and

FIG. 6C is an enlarged cross-sectional diagram of a trench opening part in the plasma etching process of the semiconductor device disclosed in Japanese Unexamined Patent Application Publication No. 2005-116822.

### DETAILED DESCRIPTION OF THE EXEMPLARY EMBODIMENTS

Hereafter, exemplary embodiments of the present invention are described with referenced to the drawings.

### First Exemplary Embodiment

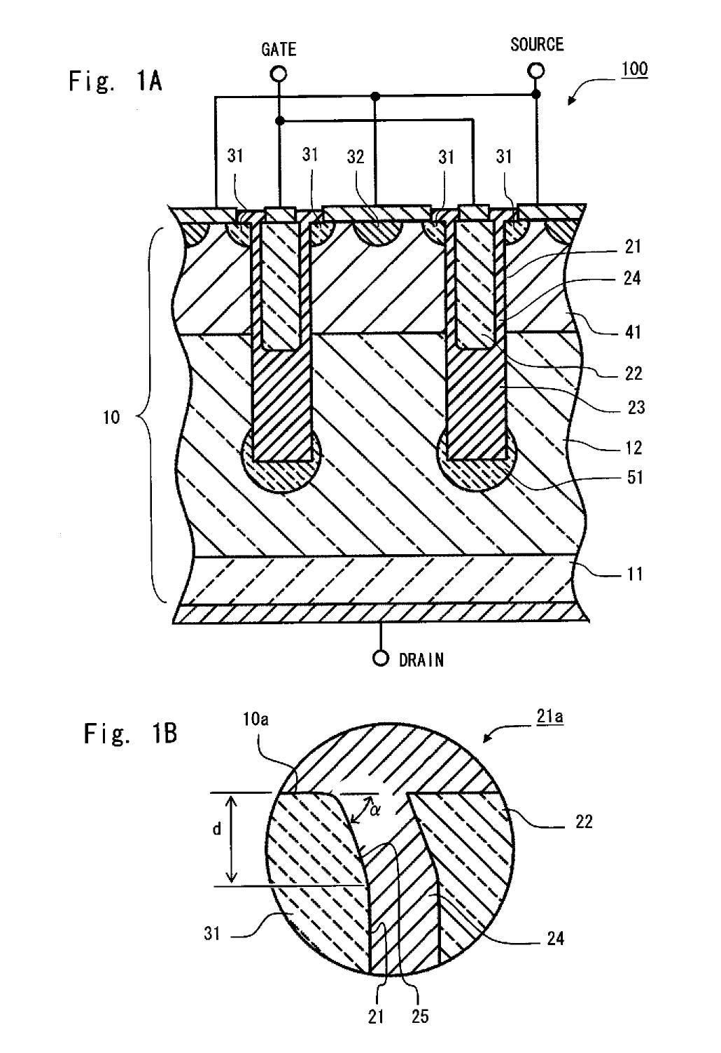

The configuration of a semiconductor device 100 according to a first exemplary embodiment is described with reference to FIG. 1A. In the first exemplary embodiment, silicon is used for the semiconductor as an example. FIG. 1A illustrates a cross-sectional configuration of the semiconductor device 100. The semiconductor device 100 is formed to a semiconductor substrate 10 which is composed of an N⁺ drain region 11, a P⁻ body region 41, an N⁻ drift region 12, an N⁺ source region 31, and a P⁺ contact region 32.

A trench 21 that penetrates the P⁻ body region 41 to reach the N⁻ drift region 12 is provided to the upper surface side of the semiconductor substrate 10. As illustrated in FIG. 1B, an inclined surface 25 with an angle of inclination a to a semiconductor substrate principal surface 10a is formed in the trench opening part 21a.

An insulating film 23, which is thicker than the gate insulating film 24, is provided to the bottom of the trench 21. The gate insulating film 24 covers the semiconductor substrate 10 and the trench 21 from the top surface of the semiconductor substrate 10 to the insulating film 23. A gate electrode 22 is provided over the insulating film 23 and the gate insulating film 24. The gate electrode 22 is opposed to the N⁺ source region 31 and the P⁻ body region 41 with the gate insulating film 24 disposed therebetween.

Further, a P floating region 51 surrounded by the N⁻ drift region 12 is provided. The P floating region 51 is in contact with the trench 21 and has a substantially circular cross-section about the bottom part of the trench 21.

In such semiconductor device 100, the conduction between the N⁺ source region 31 and the N⁺ drain region 11 is controlled by generating a channel in the P⁻ body region 41 by applying a voltage to the gate electrode 22.

Further, the thick insulating film 23 in the bottom part of the trench 21 reduces the concentration of electric fields in the corners of the lower part of the gate electrode 22 and also prevents from reducing the withstand pressure.

If the insulating film 23 does not exist, the distance between the gate electrode 22 and the N⁻ drift region 12 is larger. This reduces parasitic capacitance Cgd and increases the switching speed.

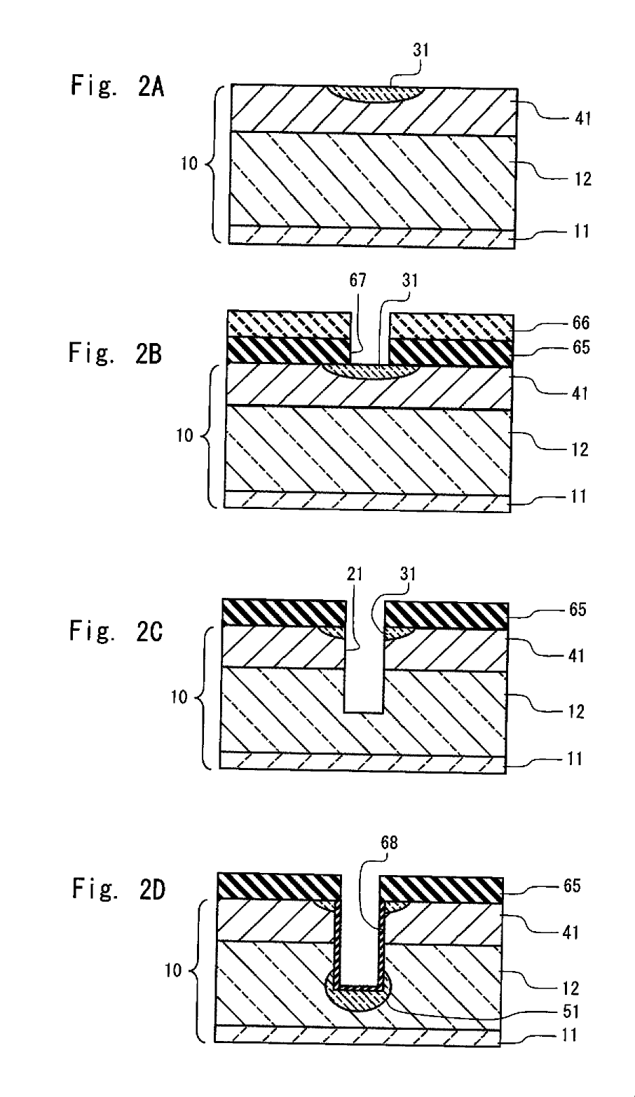

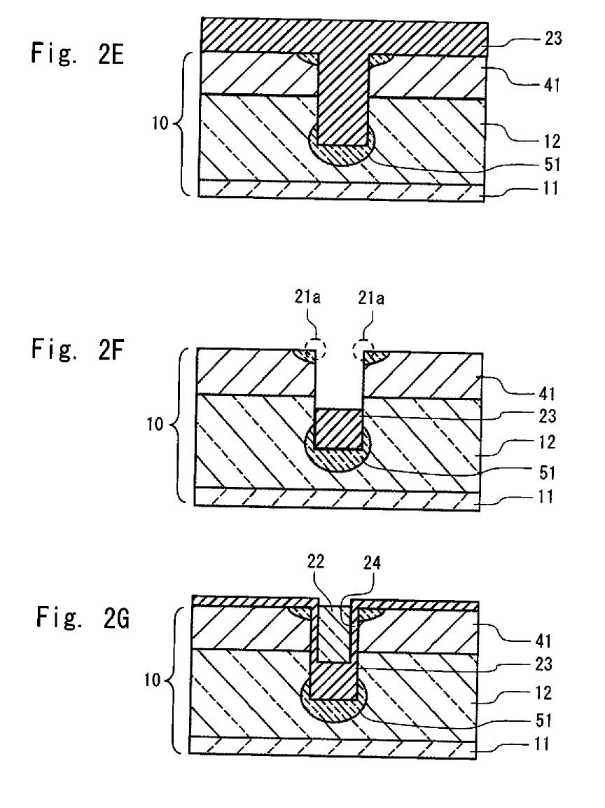

Next, the manufacturing method of the semiconductor device 100 is explained with reference to FIGS. 2A to 2G. First, as illustrated in FIG. 2A, the N⁻ drift region 12 is formed by epitaxial growth over the N⁺ substrate, which is to be the N⁺ drain region 11. Next, the P⁻ body region 41 and the N⁺ source region 31 are formed by ion implantation to fabricate the semiconductor substrate 10.

Next, as illustrated in FIG. 2B, an oxide film layer 65 is formed to the top surface of the semiconductor substrate 10 by the HTO (High Temperature Oxide) or the TEOS (TetraEthOxySilane) method. A photoresist 66 of a predetermined shape is formed over the oxide film layer 65. The oxide film layer 65 is etched using the photoresist 66 as a mask to form a groove 67 that penetrates the oxide film layer 65.

After removing the resist pattern 66, as illustrated in FIG. 2C, a dry etching is carried out using the oxide film layer 65 as a mask to form a trench 21 that penetrates the P⁻ body region 41 and reaches the N⁻ drift region 12.

Next, a thermal oxide film 68 with about 50 nm thickness is formed on the side wall of the trench 21 by carrying out thermal oxidation while leaving the oxide film layer 65, as illustrated in FIG. 2D.

Then, after carrying out ion implantation over the entire surface using the oxide film layer 65 as a mask, a thermal diffusion process is carried out to form the P floating region 51.

Next, as illustrated in FIG. 2E, the oxide film layer 65 and the thermal oxide film 68 are removed. Then, the insulating film 23 formed of NSG (Nondoped Silicate Glass) for example, is deposited over the entire surface of the semiconductor substrate 10 by CVD (Chemical Vapor Deposition) or the like so as to bury the trench 21.

Next, as illustrated in FIG. 2F, the insulating film 23 is etched back by plasma etching to form the insulating film 23 with a predetermined thickness to the bottom part of the trench 21. The trench opening part 21a is etched at the same time. Therefore, as illustrated in FIG. 1B, the inclined surface 25 at the angle of inclination a to the semiconductor substrate principal surface 10a is formed. As for the condition of this plasma etching, mixed gas with the gas flow ratio 1/6 or more and 1/4 or less of Tetrafluoromethane (CF4)/Trifluoromethane (CHF3) is used, for example. The gas pressure at that time is 6.5 Pa or more and 6.8 Pa or less, and high frequency power is 750 W or more and 850 W or less.

Next, as illustrated in FIG. 2G, the gate insulating film 24 is formed to the semiconductor substrate 10 top surface and the sidewall of the trench 21 by thermal oxidation.

Then, polysilicon is deposited inside the trench 21 by CVD for example to form the gate electrode 22.

The gate insulating film 24 is opened in the top surface side of the semiconductor substrate 10 to form a predetermined source electrode (not illustrated). A drain electrode (not illustrated) is formed to the bottom surface side. In this way, the semiconductor device 100 illustrated in FIG. 1A can be fabricated.

The manufacturing method of the semiconductor device according to the first exemplary embodiment enables to etch the insulating film 23 and also form the inclined surface 25. This suppresses the gate insulating film 24 from being locally thin in the trench opening part 21a and thereby preventing from reducing the withstand pressure caused by the concentration of electric fields.

### Second Exemplary Embodiment

In addition to the first exemplary embodiment of the present invention, the second exemplary embodiment enables to control the angle of inclination a to an appropriate angle.

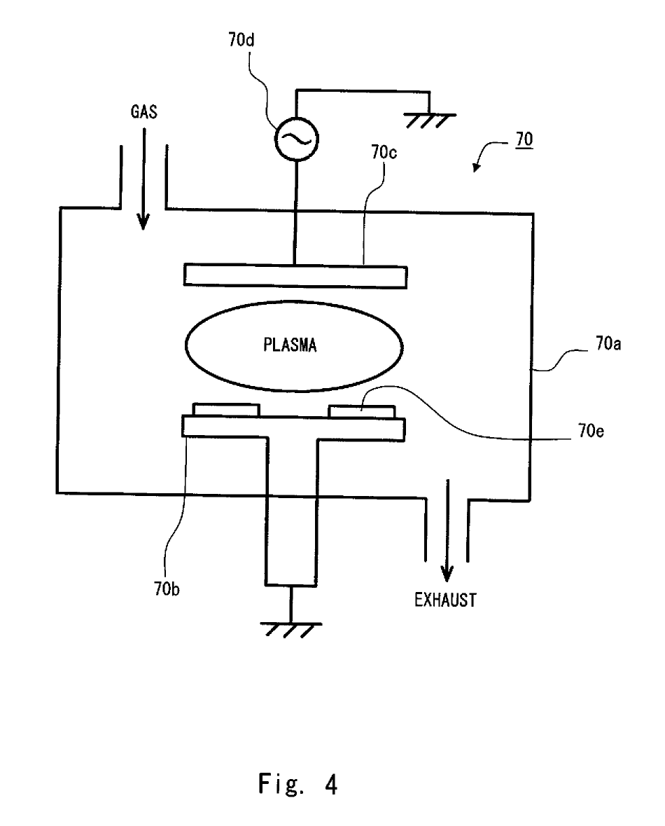

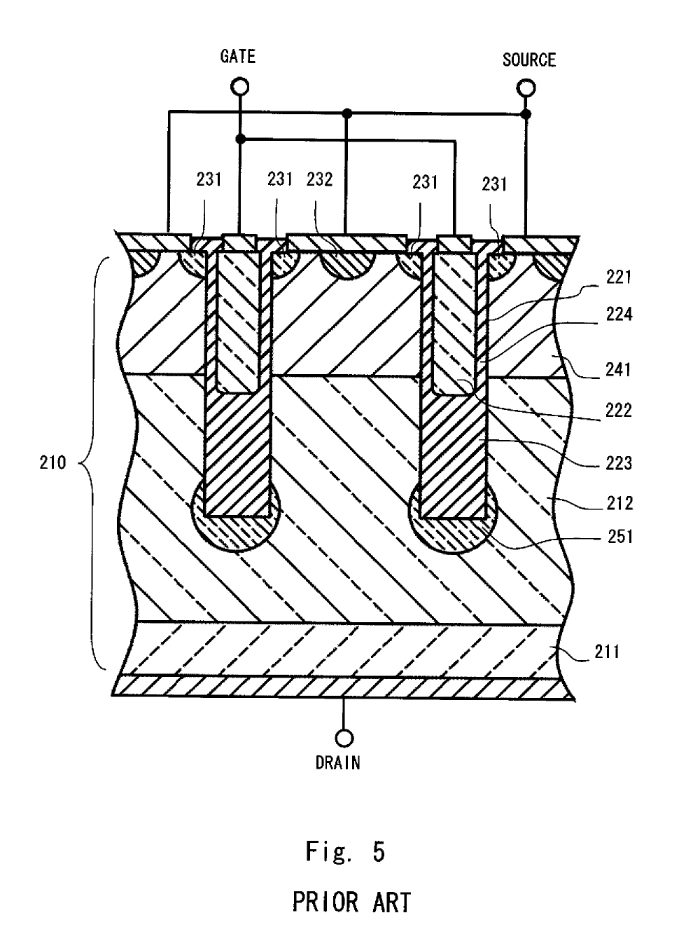

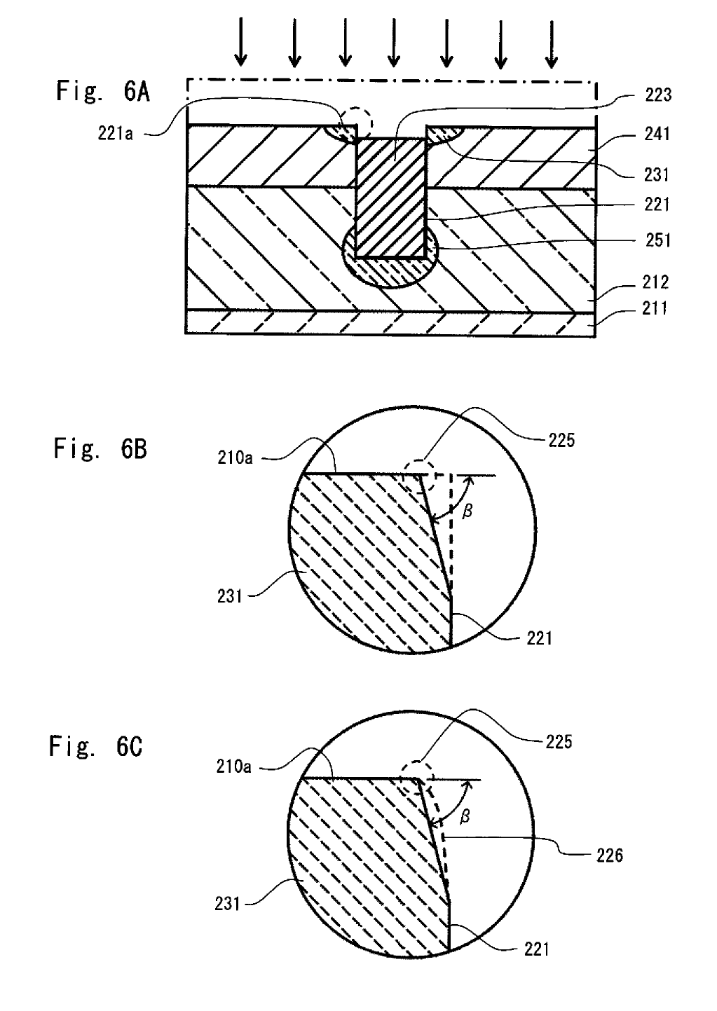

The present inventor has found that the angle of inclination a can be controlled by appropriately specifying the conditions of plasma etching. The plasma etching is carried out by a parallel plate plasma etching device 70 as illustrated in FIG. 4. In the plasma etching device 70, a lower electrode 70b and an upper electrode 70c that are also used as a wafer holder are opposed and mounted in a chamber 70a. A high-frequency power source 70d is connected to the upper electrode 70c. In order to carry out a plasma etching, reactive gas is introduced to a chamber 70a, and the high-frequency power source 70d applies high frequency power to bring the reactive gas into a plasma state. The active species in the plasma react chemically over the surface of a wafer 70e, a reaction product is separated from the surface of the wafer 70e to be exhausted, so that the plasma etching progresses.

The present inventor has investigated the relationship between the angle of inclination a and the withstand pressure. Then the present inventor has found that if the angle of inclination a is made smaller than 75 degrees, it is possible to suppress the gate insulating film 25 formed thereover from being locally thin and thereby achieving a favorable withstand pressure. Further, the lower limit of the angle of inclination a can be 45 degrees, as the angle to be a complementary angle with the angle of inclination a must not be too sharp. Thus the angle of inclination a of the inclined surface 25 suitable for preventing from reducing the withstand pressure of the semiconductor device 100 can be in the range of 45 degrees<=a<=75 degrees.

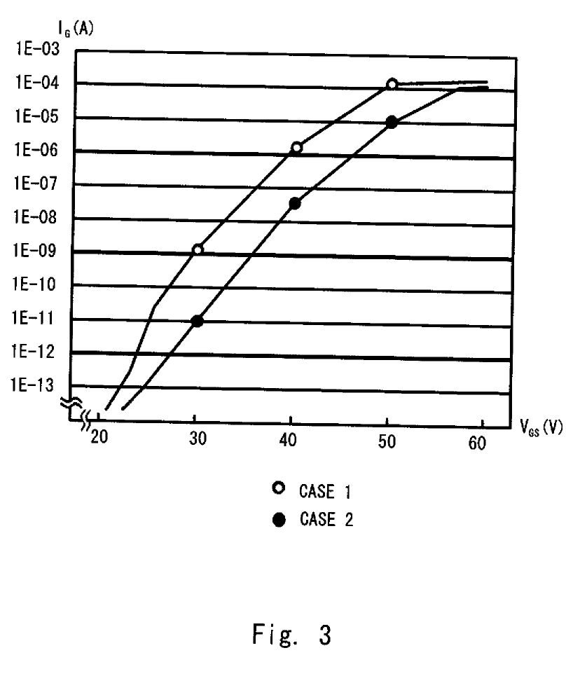

Next, in order to clarify the effect of preventing a reduction in the withstand pressure by difference of the angle of inclination a, the withstand pressure was measured in the example (case 1) of a=70 degrees, and the comparative example (case 2) of a=85 degrees. The experimental result is indicated in FIG. 3. According to FIG. 3, in the case of a=70 degrees, even though there is a fluctuation in the gate voltage V_{GS}, the gate leakage current I_{G} is reduced more than in the case of a=85 degrees. Accordingly, withstand pressure can be improved.

Mixed gas of Tetrafluoromethane and Trifluoromethane was used as the reactive gas for the plasma etching in the case of a=70 degrees, which is an example. As for the gas flow ratio, Tetrafluoromethane/Trifluoromethane=1/5, the gas pressure is 6.7 Pa, and the high-frequency power is 800 W. Under these conditions, the trench opening part 21a will not suffer an excessive plasma damage and no irregular shape is generated to form the inclined surface 25.

In the plasma etching where a=85 degrees, which is a comparative example, mixed gas of Tetrafluoromethane and Trifluoromethane was used as the reactive gas as with the case of a=70 degrees. As for the gas flow ratio, Tetrafluoromethane/Trifluoromethane=1/3, the gas pressure is 6.7 Pa, and the high-frequency power is 1000 W. The reason why the inclined surface 25 is formed to the trench opening part 21a by a plasma etching is described hereinafter. The etching speed with the reactive gas where a=70 degrees, which is an example, is faster for the semiconductor substrate 10 formed of silicon than the insulating film 23 formed of NSG. Further, in the bottom part of the trench 21, a reaction product reattaches to a side wall of the trench 21, thereby preventing from progressing to etch in the horizontal direction. Moreover, in the trench opening 21a, the reaction product hardly reattaches as compared with the bottom part of the trench 21. Therefore, in the trench opening 21a, the horizontal etching is not prevented but progresses to form the inclined surface 25.

In the case of a=70 degrees, which is an example, a depth d of the inclined surface 25 illustrated in FIG. 1B is 150 to 300 nm. If the depth d of the inclined surface falls in the abovementioned range, the angle of inclination a becomes smaller than 75 degrees. This suppresses the gate insulating film 24 that covers the trench opening part 21a from being locally thin.

The present invention is not limited to the above exemplary embodiments, but can be modified as appropriate within the scope of the present invention.

For example, P type and N type may be replaced as for the semiconductor regions.

Further, the semiconductor is not limited to silicon but may be other types of semiconductor. For example, gallium arsenide (GaAs), silicon carbide (SiC), gallium nitride (GaN), indium phosphide (InP), etc. can be used.

The insulating film 23 is not limited to NSG, but other insulating films can be used as long as the inclined surface 25 can be formed to the trench opening part 21a using the difference of etching speed with the semiconductor. For example, silicon nitride (SiN), silicon oxynitride (SiONx), etc. Further, the insulating film 23 may be a composite film formed of different insulating films.

The first and second exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

The gate insulating film 24 is not limited to silicon oxide generated by thermal oxidation but other insulating films can be used. For example, silicon nitride, silicon oxynitride, etc. Further, the insulating film 24 may be a composite film formed of different insulating films.

Further, the scope of the claims is not limited by the exemplary embodiments described above.

Furthermore, it is noted that, Applicant's intent is to encompass equivalents of all claim elements, even if amended later during prosecution.

What is claimed is:

1. A method of manufacturing a semiconductor device comprising:
forming a trench to a semiconductor substrate;
depositing an insulating film to the trench;
etching the insulating film of a bottom part of the trench by plasma etching and thereby forming to an opening part of the trench, an inclined surface at an angle of inclination a to a principal surface of the semiconductor substrate;
forming a gate insulating film from a top surface of the semiconductor substrate to the insulating film of the bottom part of the trench; and
forming a gate electrode on the gate insulating film.

2. The method according to claim 1, wherein
mixed gas of Tetrafluoromethane and Trifluoromethane is used as reactive gas in the Plasma,
a gas flow ratio (Tetrafluoromethane/Trifluoromethane) is 1/6 or more and 1/4 or less,
a gas pressure is 6.6 Pa or more and 6.8 Pa or less, and
high-frequency power is 750 W or more and 850 W or less.

3. The method according to claim 2, wherein
the gas flow ratio (Tetrafluoromethane/Trifluoromethane) is substantially 1/5,
the gas pressure is substantially 6.7 Pa, and
the high-frequency power is substantially 800 W.

4. The method according to claim 1, wherein the angle of inclination a is 45 degrees<=a<=75 degrees.

5. The method according to claim 1, wherein a depth d of the inclined surface is 150 nm<=d<=300 nm.

6. The method according to claim 1, wherein the semiconductor substrate is formed of silicon.

7. The method according to claim 1, wherein the insulating film is formed of NSG (Nondoped Silicate Glass).

8. A semiconductor device comprising:
a semiconductor substrate having a trench formed thereto;
an insulating film formed to a bottom part of the trench;
a gate insulating film formed to an inner wall of the trench and is thinner than the insulating film; and
a gate electrode surrounded by the gate insulating film, wherein
the trench has an inclined surface at an angle of inclination a to a principal surface of the semiconductor substrate formed to an opening part, and
the angle of inclination a is 45 degrees<=a<=75 degrees.

9. The semiconductor device according to claim 8, wherein a depth d of the inclined surface is 150 nm<=d<=300 nm.

10. The semiconductor device according to claim 8, wherein the semiconductor substrate is formed of silicon.

11. The semiconductor device according to claim 8, wherein the insulating film is formed of NSG (Nondoped Silicate Glass).
